(19) United States
(12) Patent Application Publication
(10) Pub. No.: US 2026/0097954 A1
(43) Pub. Date: Apr. 9, 2026

(54) ACOUSTIC LIMITER FOR MICRO-ELECTRICAL-MECHANICAL SYSTEMS (MEMS) MICROPHONES AND OTHER DEVICES

(71) Applicant: QUALCOMM Incorporated, San Diego, CA (US)

(72) Inventor: Michael MERKER, München (DE)

(21) Appl. No.: 18/910,973

(22) Filed: Oct. 9, 2024

(51) Int. Cl. B81B 7/00; B81C 1/00

(52) U.S. Cl. CPC B81B 7/0061; B81C 1/00309; B81B 2201/0257; B81B 2203/0118; B81B 2203/0127; B81B 2203/0315; B81B 2203/0353

(57) ABSTRACT

Disclosed are techniques for acoustic limiters for micro-electrical-mechanical systems (MEMS) microphones and other devices. In an aspect, an acoustic limiter comprises a first housing and a second housing separated by a flexible membrane. The membrane has at least one opening to allow air to flow between the housings. The membrane flexes in response to acoustic pressure within the first housing. If the acoustic pressure is above a threshold value, the membrane flexes a distance into the second housing such that the rigid structure completely or partially blocks the one or more openings through the membrane, which limits airflow speed into the second housing, thus limiting the acoustic pressure within the second housing. In an aspect, the acoustic limiter protects a MEMS microphone element mounted to the second housing, the first housing being the microphone input.

### BACKGROUND OF THE DISCLOSURE

### 1. Field of the Disclosure

Aspects of the disclosure relate generally to micro-electrical-mechanical systems (MEMS) microphones and other devices.

### 2. Description of the Related Art

Many consumer electronic devices require some kind of microphone. Traditional microphones are large and not well suited for miniature devices. Micro-electrical-mechanical systems (MEMS) microphones are quite small and are thus suitable for cell phones, internet of things (IoT) devices, or other use cases. Conventional MEMS microphones use piezoelectric membranes to convert acoustic waves into electrical signals. These vibrations are detected and converted to electrical impulses corresponding to the sound wave. This type of MEMS microphone is very sensitive but has the disadvantage that the membrane can be damaged by high pressure waves that can rupture the membrane, causing the MEMS microphone to lose sensitivity or lose function entirely. Atmospheric pressure sensors are another type of device having a sensor surface that is exposed to air pressure and that may be damaged by high pressure waves caused by loud noises, explosions, or large, rapid changes in air pressure due to other causes, causing the sensor to lose sensitivity or lose function entirely.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an acoustic limiter includes a first housing having a first air passage; a second housing having a second air passage and a rigid structure within the second air passage; and a flexible membrane, disposed between the first housing and the second housing, the flexible membrane having a first side, a second side opposite the first side, and at least one opening through the flexible membrane from the first side to the second side, wherein the flexible membrane is operative to flex in response to acoustic pressure within the first air passage, and, in response to acoustic pressure higher than a predetermined threshold value, the flexible membrane is operative to flex a distance into the second housing such that the rigid structure completely or partially blocks at least one opening through the flexible membrane and limits airflow speed into the second air passage, which limits the acoustic pressure within the second air passage.

In an aspect, a micro-electrical-mechanical system (MEMS) microphone with acoustic limiter includes an acoustic limiter, comprising: a first housing having a first air passage operative as an acoustic input port; a second housing having a second air passage operative as an acoustic output port and a rigid structure within the second air passage; and a flexible membrane, disposed between the first housing and the second housing, the flexible membrane having a first side, a second side opposite the first side, and at least one opening through the flexible membrane from the first side to the second side, the first side of the flexible membrane disposed at a first end of the first air passage, the second side of the flexible membrane disposed at a first end of the second air passage, wherein the flexible membrane is operative to flex in response to acoustic pressure within the first air passage, and, in response to acoustic pressure higher than a predetermined threshold value, the flexible membrane is operative to flex a distance into the second housing such that the rigid structure completely or partially blocks the at least one opening through the flexible membrane and limits airflow speed into the second air passage, which limits the acoustic pressure within the second air passage; and a MEMS microphone element, acoustically coupled to the second air passage, wherein the acoustic limiter limits the acoustic pressure to which the MEMS microphone element is subjected.

In an aspect, a method for fabricating an acoustic limiter includes providing a first housing having a first air passage; providing a second housing having a second air passage and a rigid structure within the second air passage; and providing a flexible membrane, disposed between the first housing and the second housing, the flexible membrane having a first side, a second side opposite the first side, and at least one opening through the flexible membrane from the first side to the second side, wherein the flexible membrane is operative to flex in response to acoustic pressure within the first air passage, and, in response to acoustic pressure higher than a predetermined threshold value, the flexible membrane is operative to flex a distance into the second housing such that the rigid structure completely or partially blocks at least one opening through the flexible membrane and limits airflow speed into the second air passage, which limits the acoustic pressure within the second air passage.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIGS. 1A-1D illustrate different views of a conventional micro-electrical-mechanical systems (MEMS) microphone.

FIGS. 2A-2D illustrate different views of a MEMS microphone with a discrete acoustic limiter, according to aspects of the disclosure.

FIGS. 3A-3C illustrate alternative embodiments of the flexible membrane and the rigid structure, according to aspects of the disclosure.

FIG. 4 is a cross-sectional view of a MEMS microphone with a discrete acoustic limiter, according to other aspects of the disclosure.

FIGS. 5A-5C are cross-sectional views of a MEMS microphone with an integrated acoustic limiter, according to aspects of the disclosure.

FIGS. 6A-6C are cross-sectional views of a MEMS microphone with an integrated acoustic limiter, according to other aspects of the disclosure.

FIG. 7 is a flow chart illustrating a process associated with an acoustic limiter, according to other aspects of the disclosure.

FIG. 8 illustrates a mobile device, according to aspects of the disclosure.

FIG. 9 illustrates various electronic devices that may be integrated with any device or apparatus disclosed herein.

### DETAILED DESCRIPTION

Disclosed are techniques for acoustic limiters for micro-electrical-mechanical systems (MEMS) microphones and other devices. In an aspect, an acoustic limiter includes a first housing having a first air passage, a second housing having a second air passage and a rigid structure within the second air passage, and a flexible membrane, disposed between the first housing and the second housing, the flexible membrane having a first side, a second side opposite the first side, and at least one opening through the flexible membrane from the first side to the second side. The flexible membrane is operative to flex in response to acoustic pressure within the first air passage, and, in response to acoustic pressure higher than a predetermined threshold value, the flexible membrane is operative to flex a distance into the second housing such that the rigid structure completely or partially blocks at least one opening through the flexible membrane and limits airflow speed into the second air passage, thus limiting the acoustic pressure within the second air passage. As used herein, the phrase “limiting the acoustic pressure” means limiting the maximum amplitude of a pressure wave (e.g., a sound wave) traveling through air.

In an aspect, a MEMS microphone includes an acoustic limiter mounted between a MEMS microphone element and an acoustic input port. The acoustic limiter includes a first housing having a first air passage, a second housing having a second air passage and a rigid structure within the second air passage, and a flexible membrane, disposed between the first housing and the second housing and having an opening through the flexible membrane from the first side to the second side. In response to acoustic pressure higher than a predetermined threshold value within the first air passage, the flexible membrane deforms, making contact with the rigid structure, which completely or partially blocks the opening through the flexible membrane and limits airflow speed into the second air passage, thus limiting the acoustic pressure within the second air passage, thus limiting the acoustic pressure and flow reaching the MEMS microphone element.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to”perform the described action.

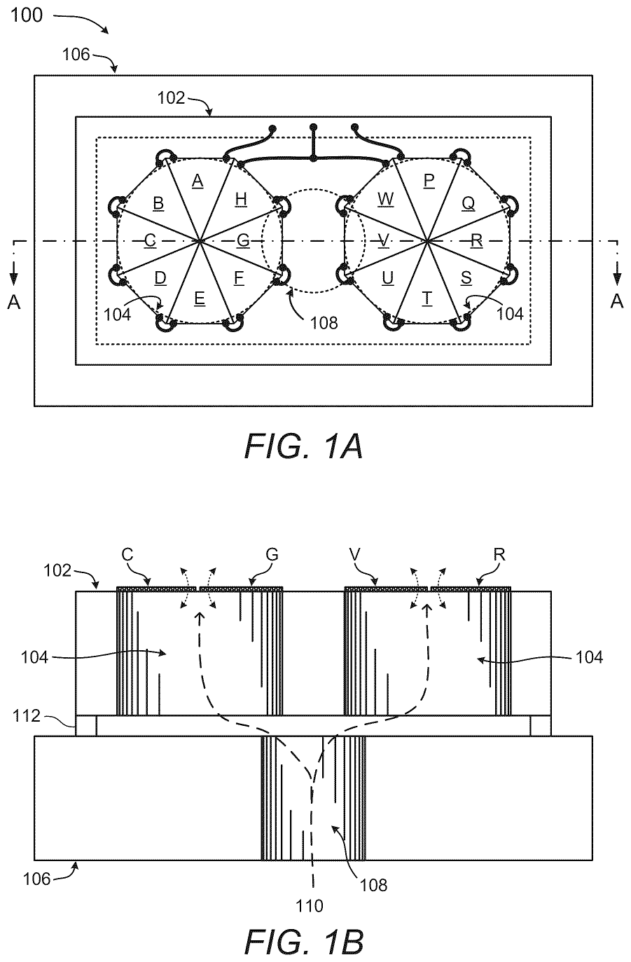

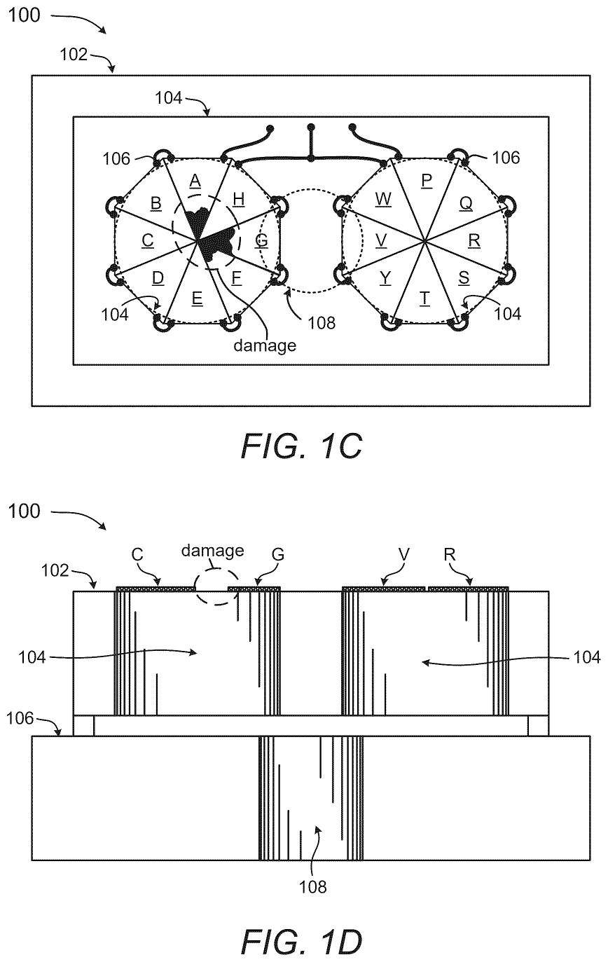

FIGS. 1A-1D illustrate different views of a conventional micro-electrical-mechanical systems (MEMS) microphone 100, which uses piezoelectric cantilever structures to convert acoustic waves into electrical signals. These structures are called cantilever structures because they have an immobile end that is mounted such that a mobile end is suspended over a cavity into which sound waves are funneled, such that the sound waves cause the suspended end to vibrate. FIG. 1A is a plan view and FIG. 1B is a cross-sectional view through cut line A-A. The MEMS microphone 100 includes a MEMS structure 102 having two sets of cantilever structures, each set suspended over an acoustic cavity 104. In the example shown in FIGS. 1A-1D, one set contains cantilever structures labeled A through H and the other set contains cantilever structures labeled P through W. The MEMS structure 102 is mounted to a substrate 106, which has an acoustic port 108 to allow sound waves to reach the acoustic cavities 104. The path 110 of the sound waves through the acoustic port 108 to the acoustic cavities 104 is shown as a dotted line. The MEMS structure 102 is mounted to the substrate 106 using a gasket 112.

In the example shown in FIG. 1A, cantilever structures A-H are wired in series, and cantilever structures P-W are wired in series. Sound waves following path 110 will cause the cantilever structures A-H and P-W to flex slightly upward and downwards, which changes the resistance of each cantilever structure. This change in resistance over time can be converted to electrical signals that correspond to the received sound. Cantilever structures can be very sensitive to sound, but they are susceptible to damage from high pressure pulses caused by very loud sounds or percussive noise, which can cause the cantilever structures to fracture and break.

FIG. 1C and FIG. 1D are a plan view and cross-sectional view, respectively, of a MEMS microphone 100 that has been damaged due to a high pressure pulse. In the example shown in FIGS. 1C and 1D, cantilever structures A, F, and G bent too far up or down in response to the high pressure pulse and as a result lost the tip of the cantilever structure. This damage not only causes the broken cantilever structure to be less able to flex, rendering it less able to detect sound waves, but air can now flow through the gaps left behind by the missing cantilever fragments, which causes the entire MEMS microphone 100 to be less sensitive or to lose function entirely.

A conventional approach to avoid such damage is to reduce the diameter of the acoustic port 108, but this can significantly reduce microphone sensitivity and does not always prevent damage. Another approach that has been proposed is to place physical structures (“limiters”) above and below the cantilever structures to limit the amount that the cantilever structures can flex, but it is very difficult to create these structures in a way that has good performance and high production yield. If the limiters are too close to the cantilever structures, the cantilever movement is impaired, causing a loss of sensitivity and injecting noise into the signal. If the limiters are too far away from the cantilever structures, the cantilever structure is not protected from damage and the limiter is ineffective for its intended purpose. Yet another approach is to create a convoluted acoustic path to the cantilever structures, but such designs have not been as effective at preventing damage to the cantilever structures as was hoped.

To address the problem of damage to MEMS microphones caused by high pressure impulses, a new structure is proposed: an acoustic limiter, which may be referred to herein as a “foil valve.”

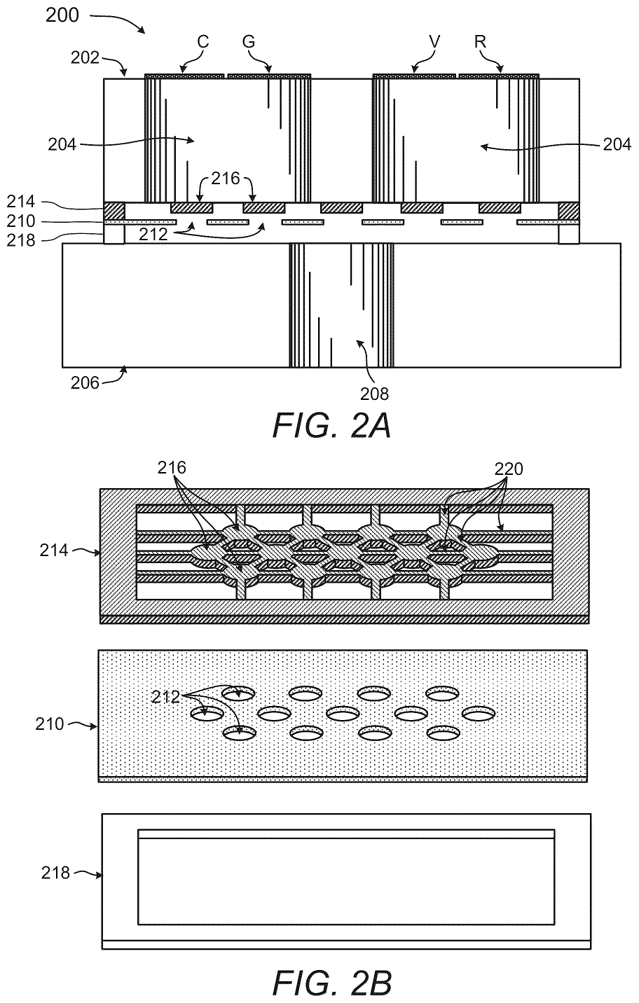

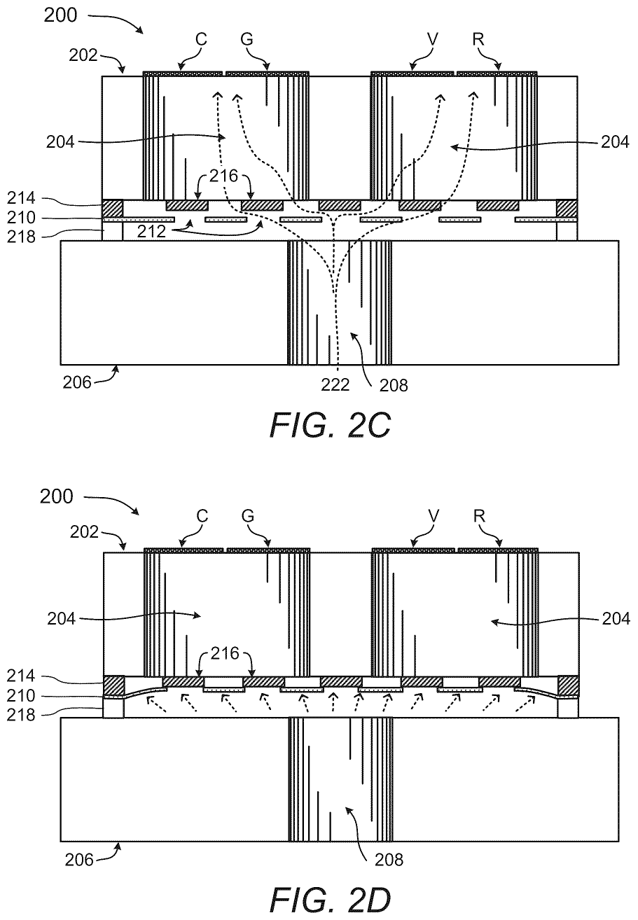

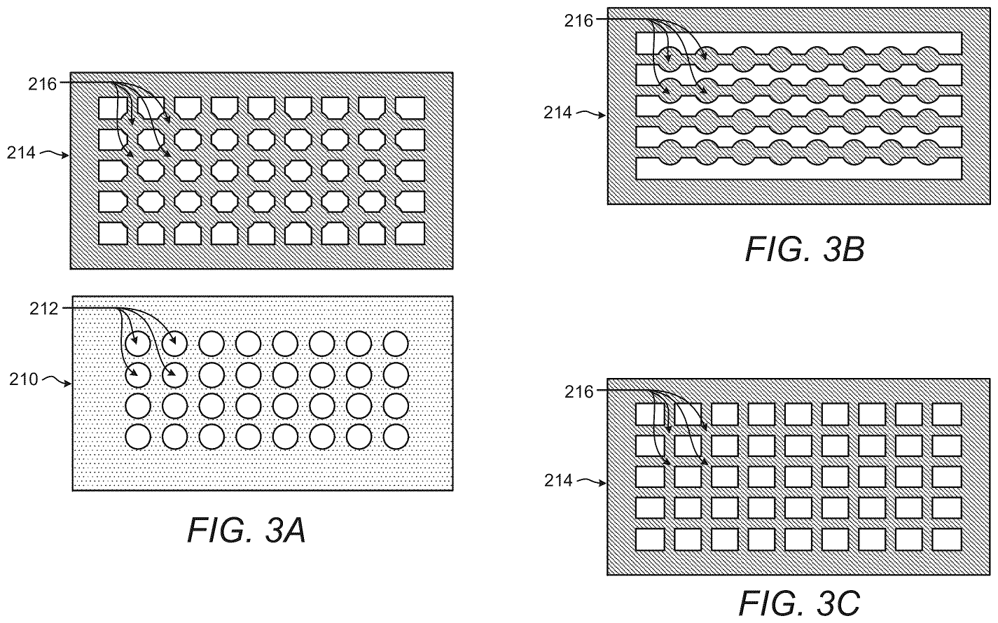

FIGS. 2A-2D illustrate different views of a MEMS microphone 200 with an acoustic limiter, according to aspects of the disclosure. FIGS. 2A-3D illustrate embodiments in which the acoustic limiter is a discrete structure that is interposed between a MEMS structure and a substrate. In another aspect, the acoustic limiter may be located at the inlet of the acoustic port, e.g., attached to the surface of the substrate opposite the MEMS structure.

FIG. 2A is a cross-sectional view of the MEMS microphone 200 showing that it includes a MEMS structure 202 having two sets of cantilever structures, each set suspended over an acoustic cavity 204. In the example shown in FIGS. 2A-2D, one set contains cantilever structures labeled A through H and the other set contains cantilever structures labeled P through W, but only cantilever structures C, G, V, and R are shown in the cross-sectional view in FIG. 2A. The MEMS structure 202 is mounted to a substrate 206, which has an acoustic port 208 to allow sound waves to reach the acoustic cavities 204. An acoustic limiter structure is disposed between the MEMS structure 202 and the substrate 206.

In the example shown in FIG. 2A, the acoustic limiter structure includes a flexible membrane 210 having one or more holes 212 through which air can pass, located below a rigid structure 214 with one or more obstructions 216 centered above the one or more holes 212. A bottom gasket 218 separates the flexible membrane 210 from the substrate 206. In some aspects, the flexible membrane 210 comprises a plastic foil. In some aspects, the bottom gasket 218 provides a gap between the flexible membrane 210 and the top surface of the substrate 206. In some aspects, the flexible membrane 210 comprises a thin plastic foil. In some aspects, the thin plastic foil comprises a plastic with a high melting point, e.g., higher than a temperature needed for reflow soldering. In some aspects the thin plastic foil comprises polyimide (PI), which has a melting point greater than 350° C. In some aspects, the thin plastic foil comprises polyethylene terephthalate (PET), which has melting point of approximately 260° C.

FIG. 2B is an exploded view of the rigid structure 214, the flexible membrane 210, and the bottom gasket 218, showing an example supports 220 within the rigid structure 214 to hold the obstructions 216 in the proper place over the holes 212 within the flexible membrane 210.

FIGS. 2C and 2D illustrate the operation of the MEMS microphone 200 with acoustic limiter, according to aspects of the disclosure. FIG. 2C shows some of the paths 222 of the sound waves through the acoustic port 208 to the acoustic cavities 204 as dotted lines. During operation with acoustic pressures within a normal operation range, the sound waves travel through the holes 212 in the flexible membrane 210, around the obstructions 216, and into the acoustic cavities 204, where the sound waves cause the cantilever structures to vibrate. During normal operation, the flexible membrane 210 may stretch or deform slightly towards or away from the rigid structure 214 before returning to its rest position shown in FIG. 2C. In some aspects, the deformation of the flexible membrane 210 may be negligible within a range of acoustic pressure that is not potentially damaging to the cantilever structures.

FIG. 2D shows the operation of the acoustic limiter during a high pressure wave. The high pressure wave causes the flexible membrane 210 to stretch upwards from its normal position until its movement is stopped by contact with the rigid structure 214. In the aspect illustrated in FIGS. 2A-2D, when the high pressure within the acoustic port 208 presses the flexible membrane 210 onto the rigid structure 214, the holes 212 in the flexible membrane 210 are blocked by the obstructions 216 in the rigid structure 214. When all of the holes 212 are blocked by the obstructions 216, the high pressure wave is prevented from reaching the cantilever structures, thus protecting them from damage. This operation may be referred to herein as “closing the foil valve.” Once the high pressure wave dissipates, the flexible membrane 210 moves away from the rigid structure 214 and soundwaves can pass through the holes 212 in the flexible membrane 210 to reach the acoustic cavities 204 as usual. In this manner, the foil valve limits the inlet dynamics to dampen loud noises without decreasing sensitivity in normal state operation.

In the example shown in FIGS. 2A-2D, there are two acoustic cavities 204, multiple holes 212 within the flexible membrane 210 and corresponding obstructions 216 in the rigid structure 214. The example shown in FIGS. 2A-2D is illustrative and not limiting, however. The number of acoustic cavities 204, the number of acoustic ports 208, the number of flexible membranes 210, the number of holes 212 in each flexible membrane 210 and the corresponding number of obstructions 216 in the rigid structure 214, and other parameters may be varied and still remain within the scope of the subject matter disclosed herein.

Example parameters that may be optimized include, but are not limited to, the composition of the flexible membrane 210, the thickness of the flexible membrane 210, the diameter of the holes 212 in the flexible membrane 210, the shape of the hole (e.g., circular, oval, square, etc.), the dimensions of the obstructions 216, the number, placement, orientation, and dimensions of support structures associated with the obstructions 216, the distance between the flexible membrane 210 and the obstructions 216, and the distance between the flexible membrane 210 and the substrate 206.

Regarding the composition of the flexible membrane 210, parameters that be considered during selection include, but are not limited to the following: stiffness, which may determine thickness; elasticity, which may determine hole diameter; and material strength, which may determine maximum inlet pressure. In some aspects, the flexible membrane 210 may be coated or laminated to improve performance or durability. In some aspect, the flexible membrane 210 may comprise a micromachined thin film, e.g., on the backside of a silicon chip.

Although the MEMS microphone shown in FIGS. 2A-2D uses cantilever structures as the microphone element, the acoustic limiter structures disclosed herein could also be used to protect other microphone element designs, including but not limited to piezoelectric membranes. The acoustic limiter structures disclosed herein could also be used to protect other devices that are exposed to air, including but not limited to atmospheric air pressure sensors, chemical “sniffers”, or other devices that may have delicate structures that could be damaged by high-pressure air pulses caused by explosions, loud noises, or other causes of large, sudden increases in air pressure.

FIGS. 3A-3C illustrate alternative embodiments of the flexible membrane 210 and the rigid structure 214, according to aspects of the disclosure. FIG. 3A shows an embodiment of the flexible membrane 210 with a 4-by-8 array of holes 212, and an embodiment of the rigid structure 214 with obstructions 216 positioned directly over the corresponding holes 212. FIG. 3B illustrates another embodiment of the rigid structure 214, but using fewer support structures to keep the obstructions 216 in place compared with the rigid structure 214 in FIG. 3A. FIG. 3C illustrates yet another embodiment of the rigid structure 214, where the obstructions 216 are not large enough to completely block the holes 212 when the flexible membrane 210 deflects and makes contact with the rigid structure 214. The embodiment shown in FIG. 3C does not completely block high pressure acoustic waves from reaching the cantilever structures but instead reduces the pressure to a value that will not damage the cantilever structures. This embodiment has the advantage that, because the foil value is never completely closed, it is less likely that a high pressure wave will rupture the flexible membrane 210. These embodiments are illustrative and not limiting.

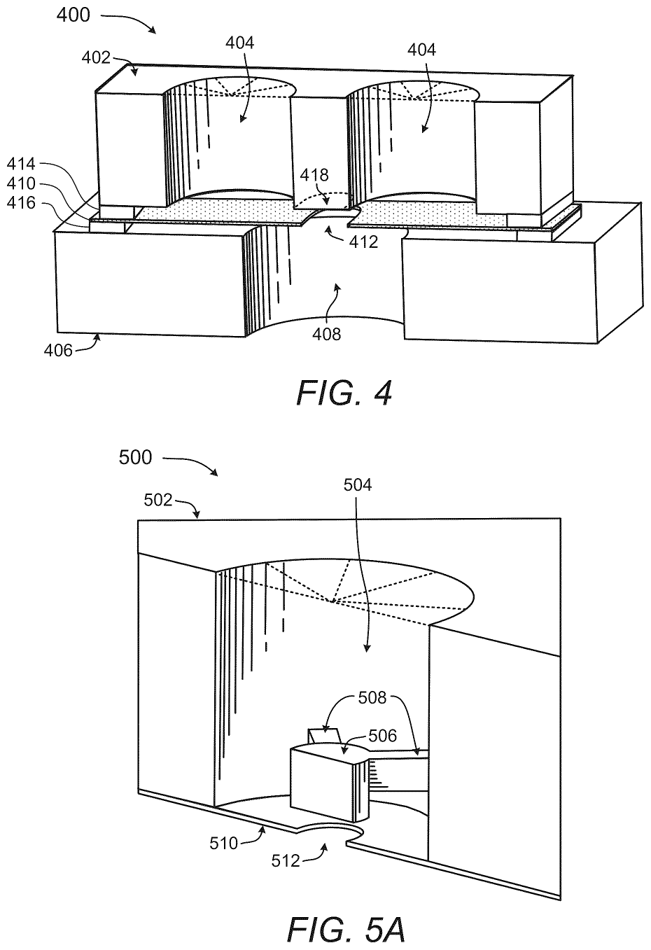

FIG. 4 is a cross-sectional view of a MEMS microphone 400 with a discrete acoustic limiter, according to other aspects of the disclosure. In the example shown in FIG. 4, a MEMS structure 402 having two sets of cantilever structures (omitted for clarity) suspended over acoustic cavities 404 is mounted to a substrate 406 having an acoustic port 408 to allow sound waves to reach the acoustic cavities 404. An acoustic limiter structure is disposed between the MEMS structure 402 and the substrate 406. In the example shown in FIG. 4, the acoustic limiter includes a flexible membrane 410 with a hole 412 positioned below a portion of the MEMS structure 402 between the two acoustic cavities 404. In the example shown in FIG. 4, the flexible membrane 410 is separated from the MEMS structure 402 by a first spacer 414, and the flexible membrane 410 is separated from the substrate 406 by a second spacer 416. In this embodiment, a high pressure wave from the acoustic port 408 will force the flexible membrane 410 up until it makes contact with the underside surface 418 of the MEMS structure 402, which blocks the hole 412 and prevents the high pressure wave from reaching and damaging the cantilever structures atop the acoustic cavities 404. In some aspects, the first spacer 414, the second spacer 416, or both, may comprise a gasket or adhesive. In some aspects, the distance between the flexible membrane 410 and the MEMS structure 402 is set by the thickness of the first spacer 414. In some aspects, the distance between the flexible membrane 410 and the substrate 406 is set by the thickness of the second spacer 416.

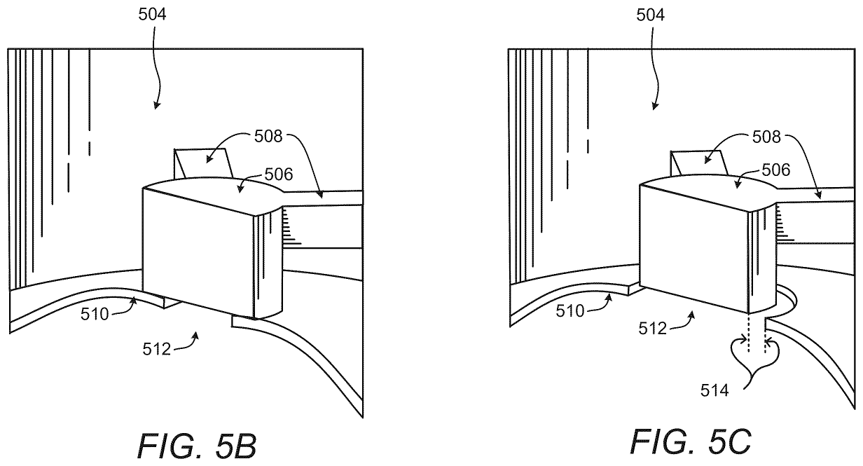

FIGS. 5A-5C are cross-sectional views of a MEMS microphone 500 with an integrated acoustic limiter, according to aspects of the disclosure. FIGS. 5A-5C illustrate embodiments in which the foil valve is integrated into the MEMS structure upon which the cantilever structures are mounted. These embodiments enable using a foil valve with single membrane microphones without the need for additional structures.

FIG. 5A shows an aspect in which the MEMS microphone 500 includes a MEMS structure 502 and a set of cantilever structures (omitted for clarity) suspended over an acoustic cavity 504. The acoustic cavity 504 contains a rigid obstruction 506 held in place by supports 508. A flexible membrane 510 having a hole 512 is mounted to a bottom surface of the MEMS structure 502 such that the hole 512 is centered below the obstruction 506. Although omitted from FIGS. 5A-5C for clarity, in some aspects, the MEMS microphone 500 is mounted to a top surface of a substrate having an acoustic port below the flexible membrane 510. This embodiment has the advantage that, in some aspects, the flexible membrane 510 can be mounted directly to a bottom surface of the MEMS structure 502 without a gasket or spacer; in other aspects, a gasket or spacer may be disposed between the MEMS structure 502 and the flexible membrane 510. Likewise, in some aspects, the flexible membrane 510 can be mounted directly to a top surface of the substrate without a gasket or spacer; in other aspects, a gasket or spacer may be disposed between the flexible membrane 510 and the substrate with the acoustic port.

FIG. 5B illustrates the operation of the foil valve during a high pressure acoustic wave: the flexible membrane 510 deforms up towards the obstruction 506 and makes contact with the bottom surface of the obstruction 506, which closes the hole 512.

FIG. 5C illustrates another aspect in which the hole 512 is larger than the obstruction 506. In this aspect, the high pressure acoustic wave causes the flexible membrane 510 to deform up towards the obstruction 506 but does not close the hole 512 completely, instead leaving a gap 514 between the flexible membrane 510 and the obstruction 506. The embodiment shown in FIG. 5C does not completely block high pressure acoustic waves from reaching the cantilever structures but instead reduces the pressure to a value that will not damage the cantilever structures. This embodiment has the advantage that, because the foil value is never completely closed, it is less likely that a high pressure wave will rupture the flexible membrane 510. These embodiments are illustrative and not limiting.

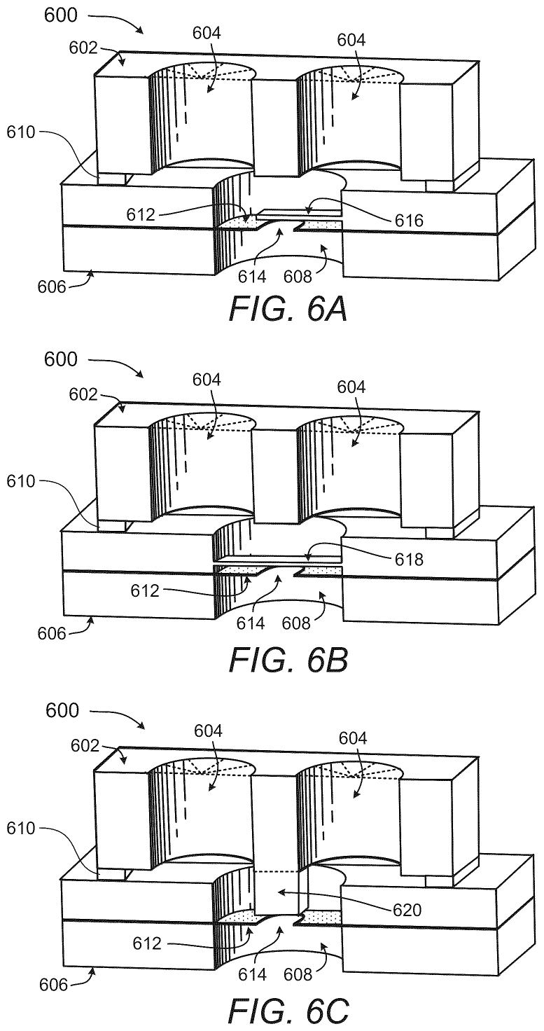

FIGS. 6A-6C are cross-sectional views of a MEMS microphone 600 with an integrated acoustic limiter, according to other aspects of the disclosure. FIGS. 6A-6C illustrate embodiments in which the foil valve is fully or partially integrated into the substrate upon which the MEMS structure and cantilever structures are mounted. In each of FIGS. 6A-6C, the MEMS microphone 600 includes a MEMS structure 602 having two sets of cantilever structures (omitted for clarity), each set suspended over an acoustic cavity 604. The MEMS structure 602 is mounted to a substrate 606 having an acoustic port 608 to allow sound waves to reach the acoustic cavities 604. In the example shown in FIGS. 6A-6C, a gasket 610 is disposed between the MEMS structure 602 and the substrate 606. A flexible membrane 612 having at least one hole 614 is mounted within the substrate 606. FIG. 6A illustrates an embodiment in which the substrate includes an obstruction 616 that extends partially across the acoustic port 608. FIG. 6B illustrates an embodiment in which the substrate includes an obstruction 618 that extends completely across the acoustic port 608. FIG. 6C illustrates an embodiment in which an extension 620 from a bottom surface of the MEMS structure 602 operates as the obstruction. The examples shown in FIGS. 6A-6C are illustrative and not limiting. The number of acoustic ports 608, the number of holes 614 and corresponding obstructions within each acoustic port 608, and the shape of the obstructions may be varied and still remain within the scope of the subject matter disclosed herein.

It is noted that the examples shown in FIGS. 4-6A are illustrative and not limiting, and that the acoustic limiters illustrated therein can be used in isolation and/or to protect devices or components other than MEMS microphone elements.

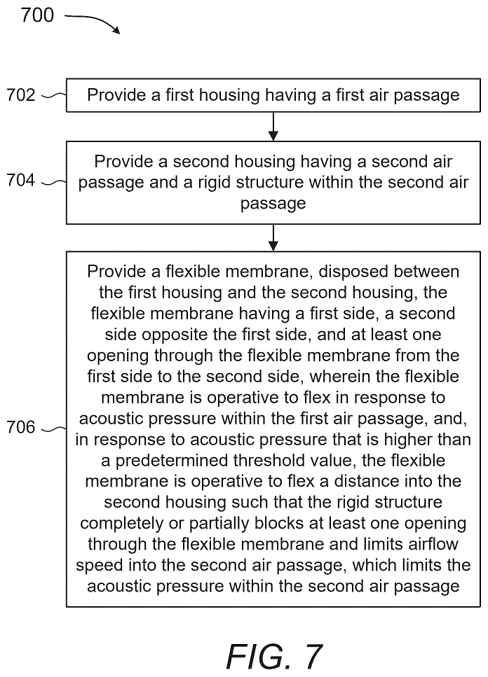

FIG. 7 is a flowchart of an example method 700 for fabricating an acoustic limiter, according to aspects of the disclosure. As shown in FIG. 7, method 700 may include, at block 702, providing a first housing having a first air passage. As further shown in FIG. 7, method 700 may include, at block 704, providing a second housing having a second air passage and a rigid structure within the second air passage. As further shown in FIG. 7, method 700 may include, at block 706, providing a flexible membrane, disposed between the first housing and the second housing, the flexible membrane having a first side, a second side opposite the first side, and at least one opening through the flexible membrane from the first side to the second side, wherein the flexible membrane is operative to flex in response to acoustic pressure within the first air passage, and, in response to acoustic pressure higher than a predetermined threshold value, the flexible membrane is operative to flex a distance into the second housing such that the rigid structure completely or partially blocks at least one opening through the flexible membrane and limits the acoustic pressure within the second air passage. In some aspects, providing the flexible membrane comprises providing a plastic foil. In some aspects, providing the plastic foil comprises providing a plastic with a melting point greater than 350 degrees Celsius. In some aspects, providing the plastic foil comprises providing a foil comprising polyimide (PI), polyethylene terephthalate (PET), or a combination thereof. In some aspects, method 700 includes providing a micro-electrical-mechanical system (MEMS) microphone acoustically coupled to the second air passage.

Method 700 may include additional implementations, such as any single implementation or any combination of implementations described below and/or in connection with one or more other methods described elsewhere herein. Although FIG. 7 shows example blocks of method 700, in some implementations, method 700 may include additional blocks, fewer blocks, different blocks, or differently arranged blocks than those depicted in FIG. 7. Additionally, or alternatively, two or more of the blocks of method 700 may be performed in parallel.

Directional terms such as upper, lower, above, and below are used herein for ease of description and often refer to illustrations in the application figures. Such terms are not necessarily descriptive of a physical direction or disposition or positioning of a device.

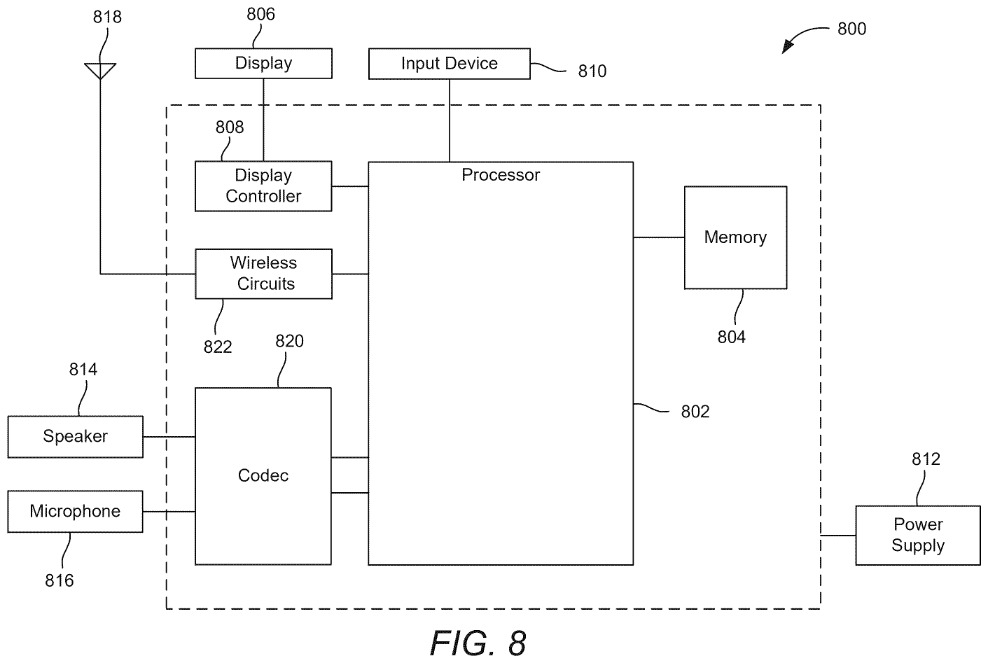

FIG. 8 illustrates a mobile device 800, according to aspects of the disclosure. In some aspects, the mobile device 800 may be implemented by including one or more IC devices manufactured based on the examples described in this disclosure.

In some aspects, mobile device 800 may be configured as a wireless communication device. As shown, mobile device 800 includes processor 802. Processor 802 may be communicatively coupled to memory 804 over a link, which may be a die-to-die or chip-to-chip link. Mobile device 800 also includes display 806 and display controller 808, with display controller 808 coupled to processor 802 and to display 806. The mobile device 800 may include input device 810 (e.g., physical, or virtual keyboard), power supply 812 (e.g., battery), speaker 814, microphone 816, and wireless antenna 818. In some aspects, the power supply 812 may directly or indirectly provide the supply voltage for operating some or all of the components of the mobile device 800.

In some aspects, FIG. 8 may include coder/decoder (CODEC) 820 (e.g., an audio and/or voice CODEC) coupled to processor 802; speaker 814 and microphone 816 coupled to CODEC 820; and wireless circuits 822 (which may include a modem, RF circuitry, filters, etc.) coupled to wireless antenna 818 and to processor 802.

In some aspects, one or more of processor 802, display controller 808, memory 804, CODEC 820, and wireless circuits 822 may include one or more IC devices including semiconductor structures manufactured according to the examples described in this disclosure.

It should be noted that although FIG. 8 depicts a mobile device 800, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

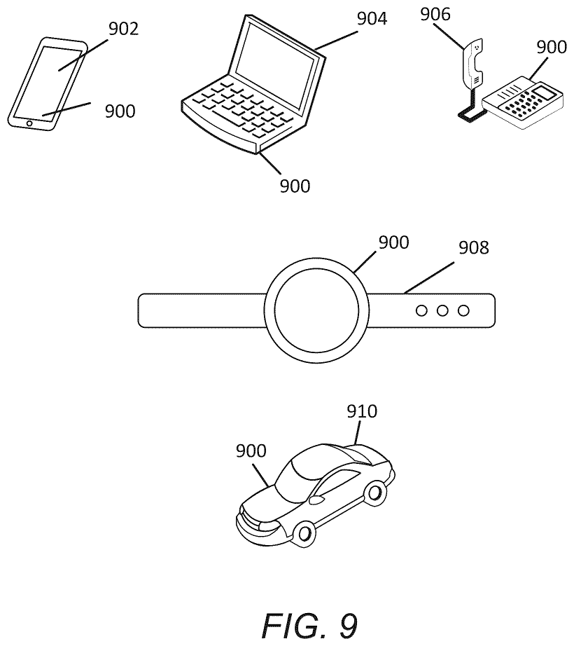

FIG. 9 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 902, a laptop computer device 904, a fixed location terminal device 906, a wearable device 908, or automotive vehicle 910 may include a semiconductor device 900 (e.g., MEMS microphone 200, 400, 500, 600) as described herein. The devices 902, 904, 906 and 908 and the vehicle 910 illustrated in FIG. 9 are merely exemplary. Other apparatuses or devices may also feature the semiconductor device 900 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

### Clause 1

An acoustic limiter, comprising: a first housing having a first air passage; a second housing having a second air passage and a rigid structure within the second air passage; and a flexible membrane, disposed between the first housing and the second housing, the flexible membrane having a first side, a second side opposite the first side, and at least one opening through the flexible membrane from the first side to the second side, wherein the flexible membrane is operative to flex in response to acoustic pressure within the first air passage, and, in response to acoustic pressure higher than a predetermined threshold value, the flexible membrane is operative to flex a distance into the second housing such that the rigid structure completely or partially blocks at least one opening through the flexible membrane and limits airflow speed into the second air passage, which limits the acoustic pressure within the second air passage.

### Clause 2

The acoustic limiter of clause 1, wherein the flexible membrane comprises a plastic foil.

### Clause 3

The acoustic limiter of clause 2, wherein the plastic foil comprises a plastic with a melting point greater than 350 degrees Celsius.

### Clause 4

The acoustic limiter of any of clauses 2 to 3, wherein the plastic foil comprises polyimide (PI), polyethylene terephthalate (PET), or a combination thereof.

### Clause 5

A micro-electrical-mechanical system (MEMS) microphone with acoustic limiter, comprising: an acoustic limiter, comprising: a first housing having a first air passage operative as an acoustic input port; a second housing having a second air passage operative as an acoustic output port and a rigid structure within the second air passage; and a flexible membrane, disposed between the first housing and the second housing, the flexible membrane having a first side, a second side opposite the first side, and at least one opening through the flexible membrane from the first side to the second side, the first side of the flexible membrane disposed at a first end of the first air passage, the second side of the flexible membrane disposed at a first end of the second air passage, wherein the flexible membrane is operative to flex in response to acoustic pressure within the first air passage, and, in response to acoustic pressure higher than a predetermined threshold value, the flexible membrane is operative to flex a distance into the second housing such that the rigid structure completely or partially blocks the at least one opening through the flexible membrane and limits airflow speed into the second air passage, which limits the acoustic pressure within the second air passage; and a MEMS microphone element, acoustically coupled to the second air passage, wherein the acoustic limiter limits the acoustic pressure to which the MEMS microphone element is subjected.

### Clause 6

The MEMS microphone of clause 5, wherein the flexible membrane comprises a plastic foil.

### Clause 7

The MEMS microphone of clause 6 wherein the plastic foil comprises a plastic with a melting point greater than 350 degrees Celsius.

### Clause 8

The MEMS microphone of any of clauses 6 to 7, wherein the plastic foil comprises polyimide (PI), polyethylene terephthalate (PET), or a combination thereof.

### Clause 9

The MEMS microphone of any of clauses 5 to 8, wherein the MEMS microphone element comprises a set of piezoelectric cantilever structures disposed at and extending over a second end of the second air passage.

### Clause 10

The MEMS microphone of any of clauses 5 to 9, wherein the MEMS microphone element comprises a piezoelectric membrane covering a second end of the second air passage.

### Clause 11

The MEMS microphone of any of clauses 5 to 10, wherein the MEMS microphone element forms at least a portion of the second housing having the second air passage, at least a portion of the rigid structure within the second air passage, or a combination thereof.

### Clause 12

The MEMS microphone of any of clauses 5 to 11, wherein at least a portion of the first housing comprises a laminate substrate.

### Clause 13

The MEMS microphone of any of clauses 5 to 12, further comprising a laminate substrate mounted to the first housing and extending the second end of the first air passage through the laminate substrate.

### Clause 14

The MEMS microphone of any of clauses 5 to 13, wherein the acoustic limiter comprises a laminate substrate.

### Clause 15

The MEMS microphone of clause 14, wherein the first housing comprises a first set of laminate layers, the second housing and rigid structure comprises a second set of laminate layers, and the flexible membrane is disposed between the first set of laminate layers and the second set of laminate layers.

### Clause 16

A method for fabricating an acoustic limiter, the method comprising: providing a first housing having a first air passage; providing a second housing having a second air passage and a rigid structure within the second air passage; and providing a flexible membrane, disposed between the first housing and the second housing, the flexible membrane having a first side, a second side opposite the first side, and at least one opening through the flexible membrane from the first side to the second side, wherein the flexible membrane is operative to flex in response to acoustic pressure within the first air passage, and, in response to acoustic pressure higher than a predetermined threshold value, the flexible membrane is operative to flex a distance into the second housing such that the rigid structure completely or partially blocks at least one opening through the flexible membrane and limits airflow speed into the second air passage, which limits the acoustic pressure within the second air passage.

### Clause 17

The method of clause 16, wherein providing the flexible membrane comprises providing a plastic foil.

### Clause 18

The method of clause 17, wherein providing the plastic foil comprises providing a plastic with a melting point greater than 350 degrees Celsius.

### Clause 19

The method of any of clauses 17 to 18, wherein providing the plastic foil comprises providing a foil comprising polyimide (PI), polyethylene terephthalate (PET), or a combination thereof.

### Clause 20

The method of any of clauses 16 to 19, further comprising providing a micro-electrical-mechanical system (MEMS) microphone acoustically coupled to the second air passage.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such. Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

What is claimed is:

1. An acoustic limiter, comprising:
a first housing having a first air passage;
a second housing having a second air passage and a rigid structure within the second air passage; and
a flexible membrane, disposed between the first housing and the second housing, the flexible membrane having a first side, a second side opposite the first side, and at least one opening through the flexible membrane from the first side to the second side,
wherein the flexible membrane is operative to flex in response to acoustic pressure within the first air passage, and, in response to acoustic pressure that is higher than a predetermined threshold value, the flexible membrane is operative to flex a distance into the second housing such that the rigid structure completely or partially blocks at least one opening through the flexible membrane and limits airflow speed into the second air passage, which limits the acoustic pressure within the second air passage.

2. The acoustic limiter of claim 1, wherein the flexible membrane comprises a plastic foil.

3. The acoustic limiter of claim 2, wherein the plastic foil comprises a plastic with a melting point greater than 350 degrees Celsius.

4. The acoustic limiter of claim 2, wherein the plastic foil comprises polyimide (PI), polyethylene terephthalate (PET), or a combination thereof.

5. A micro-electrical-mechanical system (MEMS) microphone with acoustic limiter, comprising:
an acoustic limiter, comprising:
a first housing having a first air passage operative as an acoustic input port;
a second housing having a second air passage operative as an acoustic output port and having a rigid structure within the second air passage; and
a flexible membrane, disposed between the first housing and the second housing, the flexible membrane having a first side, a second side opposite the first side, and at least one opening through the flexible membrane from the first side to the second side, the first side of the flexible membrane disposed at a first end of the first air passage, the second side of the flexible membrane disposed at a first end of the second air passage,
wherein the flexible membrane is operative to flex in response to acoustic pressure within the first air passage, and, in response to acoustic pressure that is higher than a predetermined threshold value, the flexible membrane is operative to flex a distance into the second housing such that the rigid structure completely or partially blocks the at least one opening through the flexible membrane and limits airflow speed into the second air passage, which limits the acoustic pressure within the second air passage; and
a MEMS microphone element, acoustically coupled to the second air passage, wherein the acoustic limiter limits the acoustic pressure to which the MEMS microphone element is subjected.

6. The MEMS microphone of claim 5, wherein the flexible membrane comprises a plastic foil.

7. The MEMS microphone of claim 6 wherein the plastic foil comprises a plastic with a melting point greater than 350 degrees Celsius.

8. The MEMS microphone of claim 6, wherein the plastic foil comprises polyimide (PI), polyethylene terephthalate (PET), or a combination thereof.

9. The MEMS microphone of claim 5, wherein the MEMS microphone element comprises a set of piezoelectric cantilever structures disposed at and extending over a second end of the second air passage.

10. The MEMS microphone of claim 5, wherein the MEMS microphone element comprises a piezoelectric membrane covering a second end of the second air passage.

11. The MEMS microphone of claim 5, wherein the MEMS microphone element forms at least a portion of the second housing having the second air passage, at least a portion of the rigid structure within the second air passage, or a combination thereof.

12. The MEMS microphone of claim 5, wherein at least a portion of the first housing comprises a laminate substrate.

13. The MEMS microphone of claim 5, further comprising a laminate substrate mounted to the first housing and extending a second end of the first air passage through the laminate substrate.

14. The MEMS microphone of claim 5, wherein the acoustic limiter comprises a laminate substrate.

15. The MEMS microphone of claim 14, wherein the first housing comprises a first set of laminate layers, the second housing and rigid structure comprises a second set of laminate layers, and the flexible membrane is disposed between the first set of laminate layers and the second set of laminate layers.

16. A method for fabricating an acoustic limiter, the method comprising:
providing a first housing having a first air passage;
providing a second housing having a second air passage and a rigid structure within the second air passage; and
providing a flexible membrane, disposed between the first housing and the second housing, the flexible membrane having a first side, a second side opposite the first side, and at least one opening through the flexible membrane from the first side to the second side, wherein the flexible membrane is operative to flex in response to acoustic pressure within the first air passage, and, in response to acoustic pressure that is higher than a predetermined threshold value, the flexible membrane is operative to flex a distance into the second housing such that the rigid structure completely or partially blocks at least one opening through the flexible membrane and limits airflow speed into the second air passage, which limits the acoustic pressure within the second air passage.

17. The method of claim 16, wherein providing the flexible membrane comprises providing a plastic foil.

18. The method of claim 17, wherein providing the plastic foil comprises providing a plastic with a melting point greater than 350 degrees Celsius.

19. The method of claim 17, wherein providing the plastic foil comprises providing a foil comprising polyimide (PI), polyethylene terephthalate (PET), or a combination thereof.

20. The method of claim 16, further comprising providing a micro-electrical-mechanical system (MEMS) microphone acoustically coupled to the second air passage.
